(19) United States
(12) Patent Application Publication
(10) Pub. No.: US 2009/0057904 A1
(43) Pub. Date: Mar. 5, 2009

(54) COPPER METAL LINE IN SEMICONDCUTOR DEVICE AND METHOD OF FORMING SAME

(75) Inventor: Yong Geun LEE, Eumseong-gun (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/195,086

(22) Filed: Aug. 20, 2008

(30) Foreign Application Priority Data
Aug. 27, 2007 (KR) 10-2007-0086110

(51) Int. Cl. H01L 21/768; H01L 23/535

(52) U.S. Cl. 257/751; 438/653; 257/E21.584; 257/E23.168

(57) ABSTRACT

A Cu line in a semiconductor device and method of forming same are disclosed. The method may include forming an insulating interlayer on a semiconductor substrate, forming a contact hole and a trench in the insulating interlayer in sequence, forming a short-circuit preventing layer on the insulating interlayer including the contact hole and the trench, forming a spacer on a sidewall of the trench by etching the short-circuit preventing layer, forming a Cu line layer over the semiconductor substrate including the contact hole and the trench, planarizing the Cu line layer by CMP, and forming a Cu-diffusion preventing capping layer over the semiconductor substrate including the Cu line layer.

### CROSS-REFERENCE TO RELATED APPLICATION

This application claims priority to Korean Patent Application No. 10-2007-0086110, filed on Aug. 27, 2007, which is incorporated herein by reference in its entirety.

### BACKGROUND

1. Field of the Invention

Embodiments of the present invention generally relate to a metal line in a semiconductor device, and more particularly, to a Cu line in a semiconductor device and a method of forming same. The method is suitable for preventing short-circuit of the line, among other things.

2. Discussion of the Related Art

Generally, Al, Al-alloy, W or the like is widely used as a metal in forming a metal line in a semiconductor device.

Yet, as a semiconductor device becomes highly integrated, it gets more difficult to apply such a metal to a ultra highly integrated semiconductor device due to a low melting point and high specific resistance of the metal.

Therefore, demand for developing a substitute material for a metal line has risen. Cu, Au, Ag, Co, Cr, Ni and the like are substitute materials having good conductivity. Cu or Cu-alloy has low specific resistance, good reliability on electromigration (EM), stress migration (SM), and the like as well as low product cost and is widely used.

A method of forming a Cu line in a semiconductor device according to a related art is explained with reference to the accompanying drawings as follows.

FIGS. 1A to 1E are cross-sectional diagrams for a method of forming a Cu line in a semiconductor device according to a related art.

Referring to FIG. 1A, an insulating interlayer 102 may be deposited on a semiconductor device (not shown in the drawing). A first exposure process for forming a first photoresist 106 may then be performed to form a contact hole 104. After completion of the first exposure process, the contact hole 104 may then be formed in the insulating interlayer 102 by dry etch using the first photoresist 106 as a mask.

Referring to FIG. 1B, after the first photoresist 106 has been removed, a second photoresist 107 may be formed on the insulating interlayer 102 including the contact hole by performing a second exposure process. Contact etch may then be performed such that only the contact hole 104 is filled up with the second photoresist 107.

Referring to FIG. 1C, a third exposure process may be performed to form a third photoresist 108 defining a trench to have a metal line embedded therein. The trench in which the metal line is to be embedded may then be formed in the insulating interlayer 102 by performing dry etch on the insulating interlayer 102 using the third photoresist 108 as a mask.

Referring to FIG. 1D, after the second and third photoresists 107 and 108 have been removed, a Cu line layer may be formed over the semiconductor substrate including the trench and the contact hole. The Cu line layer 110 may then be planarized by chemical mechanical polishing (CMP).

Referring to FIG. 1E, a capping layer 112 for preventing CU diffusion may be formed over the semiconductor substrate including the Cu line layer 110.

However, according to the Cu line forming method in the related art, a top-round phenomenon occurs in which a top trench portion of the insulating interlayer 102, as shown in FIG. 1D, has a semi-circular cross-section in the course of etching the insulating interlayer 102. If the Cu line layer 110 is formed over the semiconductor substrate having the top-round phenomenon and is then planarized by CMP, Cu remains on a top edge of the Cu line layer 110. This causes a short circuit between lines and reduces a process margin in forming the Cu line.

Therefore, according to the Cu line forming method in the related art, a margin against overetch by an etch process is low and CMP is not performed completely, causing inter-line short circuits. Thus reduction of line width is limited in the related art.

### SUMMARY OF SOME EXAMPLE EMBODIMENTS

In general, example embodiments of the invention relate to a Cu line in a semiconductor device that substantially obviates one or more problems due to limitations and disadvantages of the related art and a method of forming same. For example, according to an exemplary method of forming a Cu line in a semiconductor device, short circuiting of the Cu line can be prevented.

A method of forming a Cu line in a semiconductor device may include the steps of forming an insulating interlayer on a semiconductor substrate, forming a contact hole and a trench in the insulating interlayer in sequence, forming a short-circuit preventing layer on the insulating interlayer including the contact hole and the trench, forming a spacer on a sidewall of the trench by etching the short-circuit preventing layer, forming a Cu line layer over the semiconductor substrate including the contact hole and the trench, planarizing the Cu line layer by CMP, and forming a Cu-diffusion preventing capping layer over the semiconductor substrate including the Cu line layer.

Thus, after the trench has been formed, the short-circuit preventing layer is etched to enable a short-circuit preventing layer material to remain on a trench sidewall only. The short-circuit preventing material may differ from an insulating interlayer in a polish rate, whereby a process margin against over-polishing may be secured in the course of performing CMP, and whereby inter-line short circuit can be prevented.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

Aspects of example embodiments of the invention will become apparent from the following description of example embodiments given in conjunction with the accompanying drawings, in which:

FIGS. 1A to 1E are cross-sectional diagrams for a method of forming a Cu line in a semiconductor device according to a related art; and

FIGS. 2A to 2G are cross-sectional diagrams for a method of forming a Cu line in a semiconductor device according to the present invention.

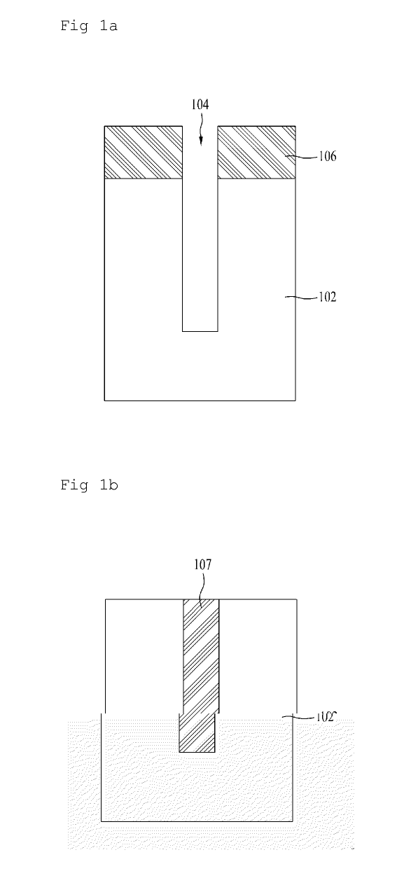

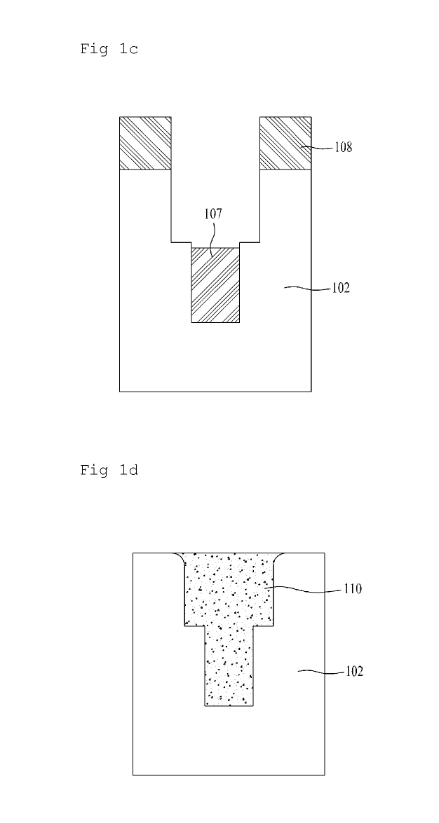

### DETAILED DESCRIPTION OF SOME EXAMPLE EMBODIMENTS

In the following detailed description of the embodiments, reference is made to the accompanying drawings that show, by way of illustration, specific embodiments of the invention. In the drawings, like numerals describe substantially similar components throughout the several views. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

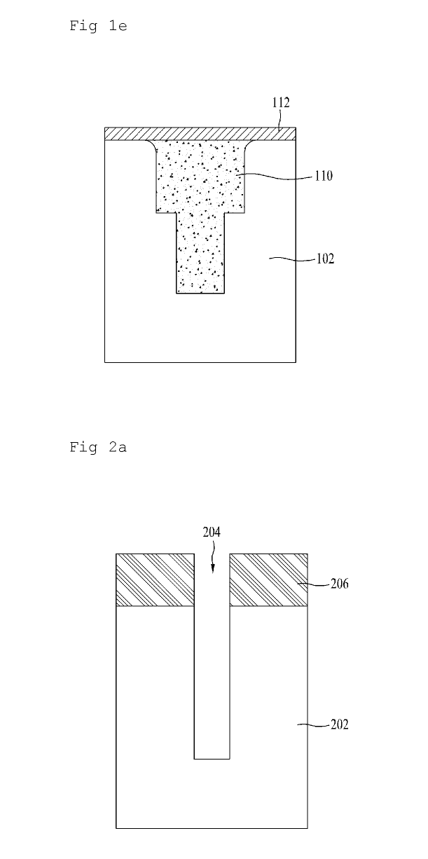

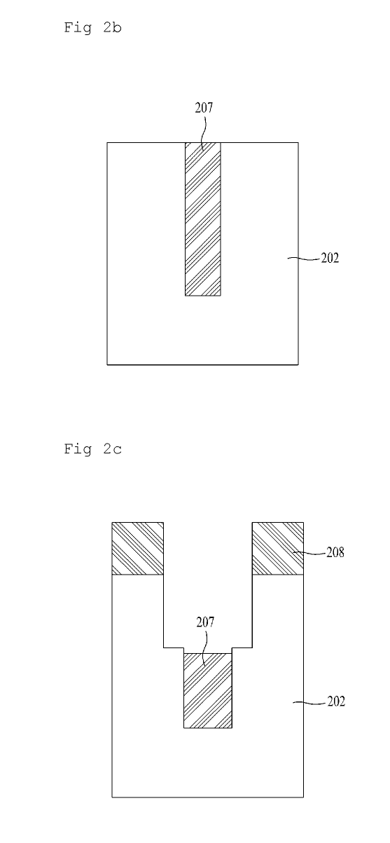

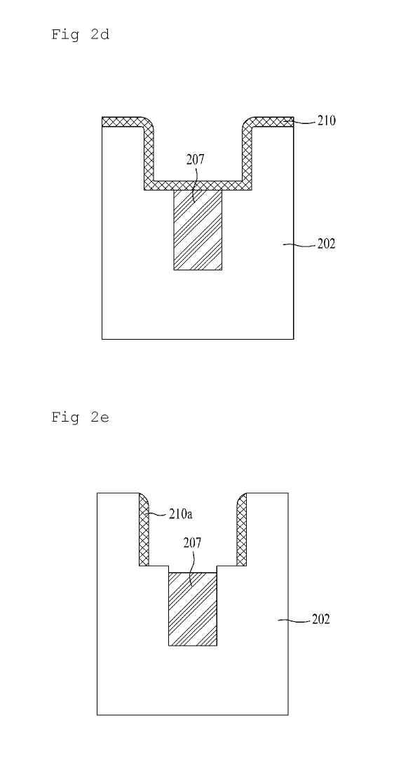

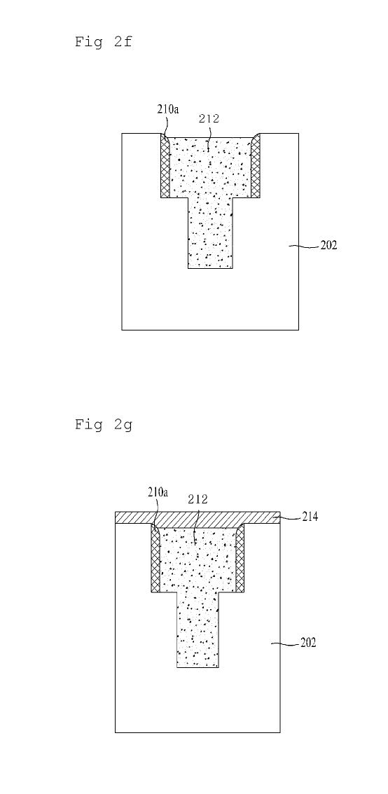

FIGS. 2A to 2G are cross-sectional diagrams for an exemplary method of forming a Cu line in a semiconductor device according to the present invention.

Referring to FIG. 2A, an insulating interlayer 202 may be deposited on a semiconductor device (not shown in the drawing). A first exposure process for forming a first photoresist 206 may then be performed to form a contact hole 204.

The first exposure process may be performed to form the first photoresist 206 by coating a photoresist layer on the semiconductor substrate (not shown in the drawing) performing exposure on the photoresist layer by exposure equipment using a prescribed exposure mask (not shown in the drawing), performing baking in baking equipment and then removing the exposed photoresist layer using a prescribed development solution.

After completion of the first exposure process, the contact hole 204 may then be formed in the insulating interlayer 202 by dry etch using the first photoresist 206 as a mask.

Referring to FIG. 2B, after the first photoresist 206 has been removed, a second photoresist 207 may be formed on the insulating interlayer 202 including the contact hole 204 by performing a second exposure process. The second photoresist 207 may then be made to remain within the contact hole 204 only by a prescribed dry etch. The prescribed dry etch may include reactive ion etch (RIE).

In one embodiment, the contact hole 204 may be filled up with Novloc, for example, as the second photoresist 207. Novloc is a photoresist component non-reactive with light that, when provided within the contact hole 204, prevents the contact hole 204 from being affected by the trench forming step.

Referring to FIG. 2C, a third exposure process may be performed to form a third photoresist 208 defining a trench to have a metal line embedded therein. The trench in which the metal line is to be embedded may then be formed in the insulating interlayer 202 by performing dry etch on the insulating interlayer 202 using the third photoresist 208 as a mask.

Referring to FIG. 2D, after the third photoresist 208 has been removed, a short-circuit preventing layer 210 may be formed over the semiconductor substrate including the trench and the contract hole.

The short-circuit preventing layer 210 can include a silicon nitride (SiN) layer with a different polishing rate than that of the insulating interlayer 202.

Referring to FIG. 2E, a spacer 210a may be formed by performing dry etch on the short-circuit preventing layer 210 over the semiconductor substrate without any special pattern process by a photoresist. In particular, the spacer 210a may be formed by performing a blank etch process such that the short-circuit preventing layer 210 remains on a trench sidewall.

Referring to FIG. 2F, after the second photoresist 207 remaining within the contact hole 204 has been removed, a Cu line layer 212 may be formed over the semiconductor substrate including the trench and the contact hole. The Cu line layer 110 may then be planarized by CMP until a surface of the insulating interlayer 202 is exposed.

In performing the CMP, since the spacer 210a formed on the sidewall of the trench differs from the insulating interlayer 202 in a polishing rate, a process margin for over-polishing according to the difference of the polishing rate is ensured. Therefore, an inter-line short circuit may be prevented by sufficiently polishing out portions that could possibly cause a short-circuit.

Referring to FIG. 2G, a capping layer 214 for preventing Cu diffusion may be formed over the semiconductor substrate including the Cu line layer 212.

While the present invention has been described with respect to the preferred embodiment, it will be apparent to those skilled in the art that various changes and modifications may be made without departing from the scope of the present invention as defined in the following claims.

What is claimed is:

1. A method of forming a Cu line in a semiconductor device, comprising the steps of:
forming an insulating interlayer on a semiconductor substrate;
forming a contact hole and a trench in the insulating interlayer in sequence;
forming a short-circuit preventing layer on the insulating interlayer including the contact hole and the trench;
forming a spacer on a sidewall of the trench by etching the short-circuit preventing layer;
forming a Cu line layer over the semiconductor substrate including the contact hole and the trench;
planarizing the Cu line layer by CMP; and
forming a Cu-diffusion preventing capping layer over the semiconductor substrate including the Cu line layer.

2. The method of claim 1, the step of forming the contact hole and the trench in the insulating interlayer, comprising the steps of:
forming a second photoresist on the insulating interlayer including the contact hole;
performing a prescribed dry etch that leaves the second resist within the contact hole;
forming a third photoresist on the insulating interlayer to expose an area of the trench; and
forming the trench in the insulating interlayer by a prescribed dry etch using the third photoresist.

3. The method of claim 2, wherein the second photoresist is formed by Novloc.

4. The method of claim 2, wherein the prescribed dry etch comprises reactive ion etch (RIE).

5. The method of claim 1, wherein the short-circuit preventing layer is etched by a blank etch.

6. The method of claim 1, wherein the short-circuit preventing layer comprises a silicon nitride (SiN) layer differing from the insulating interlayer in a polishing rate.

7. A Cu line in a semiconductor device, comprising:
an insulating interlayer on a semiconductor substrate;
a contact hole and a trench in the insulating interlayer;
a spacer on a sidewall of the trench;
a Cu line layer planarized within the contact hole and the trench; and
a Cu-diffusion preventing capping layer over the semiconductor substrate including the Cu line layer.

8. The Cu line of claim 7, wherein the spacer comprises a silicon nitride (SiN) layer differing from the insulating interlayer in a polishing rate.
